(19) United States
(12) Patent Application Publication
(10) Pub. No.: US 2008/0013292 A1
(43) Pub. Date: Jan. 17, 2008

(54) Rollable Electronic Panel Device

(75) Inventors: Peter Jan Slikkerveer, Eindhoven (NL); Petrus Cornelis Paulus Bouten, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 10/598,747

(22) PCT Filed: Mar. 7, 2005
(86) PCT No.: PCT/IB05/50827

§ 371 Date: May 8, 2007

(30) Foreign Application Priority Data
Mar. 16, 2004 (EP) 04101063.8

(51) Int. Cl. H05K 1/00

(52) U.S. Cl. 361/749

(57) ABSTRACT

A device (1) having a panel (3) and/or a supporting mechanism (5) consisting of thin, flexible material that can be rolled up itself. This flexibility reduces greatly the chance of damage. To make this flexible mechanism support the unrolled display, the structure is curved in the direction perpendicular to the unrolling direction.

The invention relates to a panel device having an electronic panel, the electronic panel being movable between a first position and a second position in which the electronic panel device has a housing, which comprises the electronic panel in one of said first and second positions.

The panel device may be a touch screen or a display device belonging to one of the groups of (organic) light emitting devices, liquid crystal display devices, electrochromic display devices, electrophoretic display devices and reflective display devices including an interferometric modulator and luminescent display devices. The display devices may be passive or active matrix display devices. Examples of such active matrix display devices are TFT-(O) LED devices, TFT-LCDs or AM-LCDs, which are used in laptop computers and in organizers, but also find an increasingly wider application in GSM telephones.

In many applications nowadays, like laptop computers and organizers (but of course also in GSM telephones) portable (display) devices are preferred. To this end more and more flexible (display) panel devices are used. The flexibility of flexible (display) panel devices and particularly roll-up (display) panel devices originates from the lack of rigidity of the (display) panel devices themselves. This is partially caused by the low modulus of their substrates (e.g. plastics) but mostly by their extreme low thickness (say below 0.5mm).

In the case of a roll-up display, this lack of rigidity however poses problems in usage when unrolled. So an extra supporting mechanism is needed, in use, which ensures the display to be kept “flat” so that the user can access the information on the display. This can be solved with an additional mechanism that can unfold the display when needed. Besides adding additional volume and weight to the device, such an additional mechanism usually suffers from reduced stiffness and increased fragility when extended.

The invention has as its goal to solve at least partly the above-mentioned problem. To this end at least one of an electronic panel or a panel support is rollable in a rolling direction, the part of the electronic panel or the panel support outside the housing having a substantially linear cross—section in a plane parallel to the rolling direction and a curved cross—section in the direction perpendicular to the rolling direction.

In fact the invention uses an elastic, roll-up supporting mechanism that can either be incorporated in the display itself (e.g. as a substrate of the (display) panel device) or can be performed by additional supporting roll-up mechanism(s). Especially this supporting mechanism consists of thin, flexible material that can be rolled up itself like a metal substrate. The presence of a separate support behind the display reduces greatly the chance of damage when the (display) panel device is extended.

To give this flexible material a curved form several measures at the exit of the housing are possible. Said may for instance have a curved slit, the slit having a form substantially equal to the curved cross - section in the direction perpendicular to the rolling direction. In this case the whole panel device is curved, such as e.g. in the case of an (organic) light emitting device on a metal substrate.

On the other hand the housing may have a wider opening and a mechanism to induce the curving when the device is unrolled. For example it may have an opening with one side having a form substantially equal to the curved cross—section in the direction perpendicular to the rolling direction. The other side may be non-curved e.g. when a curved substrate carries a less curved or non-curved panel device or for (un)rolling the substrate when it is not yet curved. In this case the housing further may have a lid having substantially the same form as said less curved or non-curved side. Closing the lid will enforce the desired curvature on the device by pushing the center of the device down, while the edges are supported by the curved side of the slit.

These and other aspects of the invention are apparent from and will be elucidated with reference to the embodiments described hereinafter.

### In the drawings:

FIG. 1 shows a first embodiment of the invention having a panel device with a rollable display panel and/or touch panel according to the invention,

FIG. 2 shows another device according to the invention,

FIG. 3 shows a housing of another device according to the invention, while

FIGS. 4 and 5 show other, further embodiments of a device according to the invention and

FIG. 6 shows a part of a device according to the invention.

The Figures are diagrammatic and not drawn to scale. Corresponding elements are generally denoted by the same reference numerals.

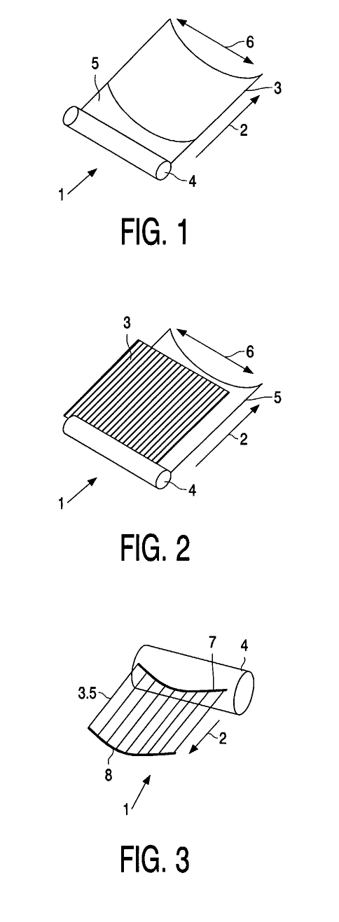

FIG. 1 shows a panel device 1 comprising in this example a rollable display 3, which is provided inside a housing 4. The housing may comprise further driving electronics and e.g. batteries. FIG. 1 shows an unrolled display 3 provided on a substrate 5, which has been unrolled in a rolling direction (unrolling direction) indicated by arrow 2.

According to the invention, during rolling or in a later stage, the structure outside the housing, in this example comprising the display 3 and substrate 5, is curved in the direction perpendicular to the rolling direction (see double-arrow 6, FIG. 1). In the rolling direction, indicated by arrow 2 in FIG. 1, the part of the structure outside the housing has a substantially linear cross—section in a plane parallel to the rolling direction.

The nature of mechanics allows a location at such a thin substrate to be curved only in one direction simultaneously, while the magnitude of the curvature and its direction might vary over the surface in the other direction.

By imposing the curvature as proposed in this invention all positions along the surface of the film are curved in the imposed direction perpendicular to the rolling direction (see double-arrow 6), not allowing curvature in the rolling direction.

Since the mechanism in this case is based on a flexible substrate, the structure (display), as it were, forms its own support and no additional support structure is used. This corresponds, as it were, with the use of a paper sheet and has the advantage that there is no additional structure needed (minimal weight, volume, minimal cost).

FIG. 2 shows a support structure, where a display 3 is added on top of a substrate layer 5 (e.g. a thin flexible metal sheet). The display 3 in this example is more flexible than the substrate layer 5 which is too thin for supporting itself mechanically). The two layers 3,5 may be rolled up simultaneously or separately on the same roll or on two separate rolls while each of them may comprise separate parts of the display function, such as reflectors or backlights.

On the other hand the device or the support may be preshaped in the desired shape as its equilibrium state (comparable to a roll-up tape measure). The metal film is now pre-curved in the desired direction. During the roll-up this support structure deforms elastically to a flat film, which can be rolled up. Besides for metal, this can equally be applied using polymer and inorganic s. Instead of pre-curving the display or the full supports, it is also possible to attach a pre-curved, elastic top connection to the pulling end of the structure.

Instead of pre-curving the display or the full supports, it is also possible to attach a pre-curved, elastic top connection to the pulling end of the structure or at some positions along the device.

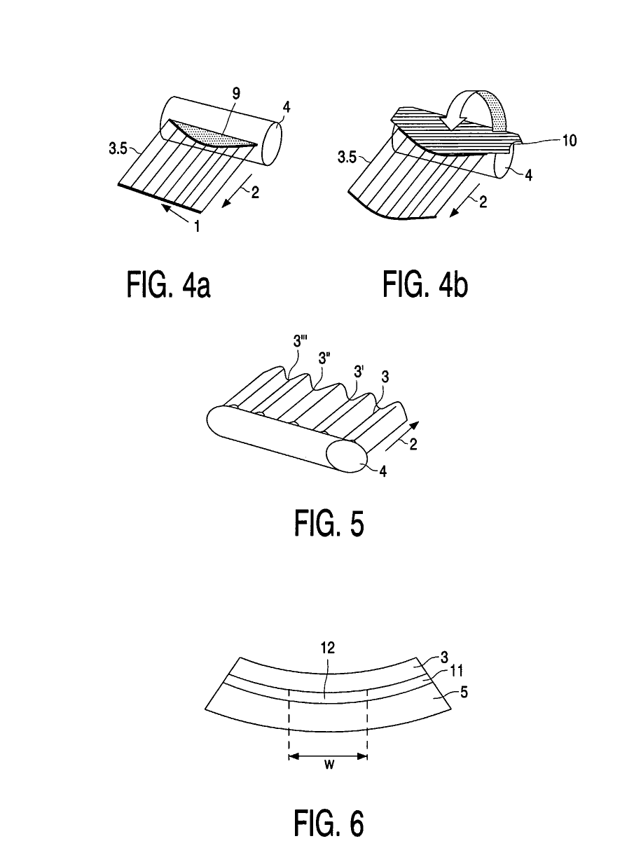

FIGS. 3 and 4 show some embodiments of a structure 3, 5 having a flat display or support mechanism that is curved either during unrolling of the display or after unrolling.

In FIG. 3 the structure 3, 5 is rolled through a curved slit 7 in the housing 5.

In this manner the display or support structure is forced into the intended shape. This can be combined with a fixed reinforcement 8 at the end of the structure with the same or a comparable shape as the slit 7. The elastic reinforcement may serve as a top connection or grip to the pulling end.

FIG. 4 shows an embodiment where the display or support structure 3,5 is curved after unrolling. This is achieved by unrolling the structure via an opening 9 as a flat sheet (FIG. 4a) and then closing a lid 10 with the intended curvature, forcing the display into its curved shape (FIG. 4a). In the example of FIG. 4 a moon-shaped slit or opening 9 in the display housing is shown, which makes the display change shape between the flat and the curved state. The slit may also have other forms such as a rectangular form in which the curving is forced unto the structure by notches.

The protective scope of the invention is not limited to the embodiments described. For instance more than one structure can be integrated in the device (see FIG. 5 comprising four structures 3ⁱ, 3ⁱⁱ, 3ⁱⁱⁱ, 3^{iv}). This embodiment might be advantageous for wide displays, where a single structure 3 would be insufficient in bringing the desired stiffness.

The support may have the desired shape at its equilibrium state (comparable to a roll-up tape measure). This may be achieved in various ways e.g. by plastically deforming the (metal)substrate 5, e.g. by pre-curving in the desired direction. Another alternative to achieve this pre-curved state is using predetermined elastic deformations, e.g. using thermal mismatch of different layers, or application of stretched layers.

Fixation of two layers in a pre-defined curved shape (in the direction normal to direction 2 is shown schematically in FIG. 6

In the method the adhesive layer 11 is not necessarily continuous. When the width w of an adhesion-free zone 12 is chosen appropriately, a “buckling” phenomenon can be used to (pre)bend the cell in the direction normal to direction 2.

The lower substrate is not necessarily continuous in the direction 2 either.

During roll-up such a support structure deforms elastically to a flat film, which can be rolled up. Besides for metal, this can equally be applied using polymer and inorganic materials. Instead of pre-curving the display or the full supports, it is also possible to attach a pre-curved, elastic top connection to the pulling end of the structure.

The invention resides in each and every novel characteristic feature and each and every combination of characteristic features. Reference numerals in the claims do not limit their protective scope. Use of the verb “to comprise” and its conjugations does not exclude the presence of elements other than those stated in the claims. Use of the article “a” or “an” preceding an element does not exclude the presence of a plurality of such elements.

1. A panel device having an electronic panel, the electronic panel being movable between a first position and a second position in which the electronic panel device has a housing, which comprises the electronic panel in one of said first and second positions, at least one of an electronic panel or a panel support being rollable in a rolling direction, the part of the electronic panel or the panel support outside the housing having a substantially linear cross-section in a plane parallel to the rolling direction and a curved cross-section in the direction perpendicular to the rolling direction.

2. An electronic panel device according to claim I having enforcement parts along the edges of the electronic panel.

3. A panel device according to claim 1, the part of the electronic panel or the panel support outside the housing having in the direction perpendicular to the rolling direction a curved cross-section comprising multiple curves.

4. A panel device according to claim 1, the housing having means for curving the electronic panel or a panel support at an exit opening

5. A panel device according to claim 4, the housing having a curved slit, the slit having a form substantially equal to the curved cross-section in the direction perpendicular to the rolling direction.

6. An electronic panel device according to claim 4, the housing having a mechanism for forcing the electronic panel or the panel support in the curved state after unrolling the device

7. An electronic panel device according to claim 6 having an opening with one side having a form substantially equal to the curved cross-section in the direction perpendicular to the rolling direction, the housing further having a lid having substantially the same form as said side, that by closing the lid forces the electronic panel or the panel support in the desired curvature.
